(19) United States
(12) Patent Application Publication
(10) Pub. No.: US 2016/0202606 A1
(43) Pub. Date: Jul. 14, 2016

(54) CORE-SHELL NANOPARTICLES, METHODS OF MAKING SAME, AND USES OF SAME

(71) Applicant: THE RESEARH FOUNDATION FOR THE STATE UNIVERSITY OF NEW YORK, Amherst, NY (US)

(72) Inventors: Paras N. Prasad, Williamsville, NY (US); Tymish Y. Ohulchanskyy, Amherst, NY (US); Guanying Chen, Buffalo, NY (US); Hongsub Jee, Seoul (KR)

(21) Appl. No.: 14/916,018

(22) PCT Filed: Sep. 3, 2014
(86) PCT No.: PCT/US14/53863

§ 371 Date: Mar. 2, 2016

Related U.S. Application Data
(60) Provisional application No. 61/872,890, filed on Sep. 3, 2013.

(51) Int. Cl. G03F 7/004; G03F 7/20; G01N 21/64; G03F 7/038

(52) U.S. Cl. CPC G03F 7/0046; G03F 7/0385; G03F 7/2051; G01N 21/6428; G01N 2201/06113

(57) ABSTRACT

Provided are core-shell nanoparticles and methods of making and using the nanoparticles. The nanoparticles comprise a core comprising hexagonal phase p-NaYbF₄ doped with Tm and shell comprising NaYF₄, NaLuF₄, or NaGdF₄. The core-shell nanoparticles can be used to upconvert near infrared light to UV or visible blue light, which can polymerize photopolymerizable materials. The core-shell nanoparticles can be used in applications such as, for example, photolithography applications, photopatterning applications, fabrication of polymer coatings, medical applications, dental applications, and anti-counterfeiting applications.

### CROSS-REFERENCE TO RELATED APPLICATIONS

This application claims priority to U.S. provisional patent application No. 61/872,890, filed Sep. 3, 2013, the disclosure of which is incorporated herein by reference.

### STATEMENT REGARDING FEDERALLY SPONSORED RESEARCH

This invention was made with government support awarded by grant No. FA95500910258 through the United States Air Force Office of Scientific Research. The Federal Government has certain rights in this invention.

### FIELD OF THE DISCLOSURE

This disclosure relates generally to the field of nanoparticles, and particularly to β-NaYbF₄:Tm³⁺/β-NaZF₄ (Z═Y, Gd, or Lu) core/shell nanoparticles.

### BACKGROUND OF THE DISCLOSURE

Photopolymerization is widely utilized in various fields. For example, photopolymerization is used to cure coating films, form planographic printing plates, prepare photoresists and photomasks, and to make black-and-white or color transfer and coloring sheets. Further, photopolymerizable compositions are used in the field of dentistry. In most instances, photopolymerization is achieved by irradiation with ultraviolet (UV) or short-wave visible light.

Typically, a photopolymerizable composition comprises a monomer and a photopolymerization initiator. When UV and short-wave visible light is used to polymerize these photopolymerizable compositions, the light transmission is adversely affected by the hue of the composition or the filler, and the degree of the curing is changed according to the hue or the amount of the filler added. Application of UV radiation in photopolymerization has at least three significant disadvantages: First, the UV radiation used for curing is unsafe to living organisms. For this reason, the source of the UV irradiation must be housed within a carefully shielded assembly in order to minimized chances of harmful exposure. Second, a significant amount of reactive ozone is produced by the UV source. For this reason, the curing system must be vented out. Third, UV radiation cannot produce bulk three-dimensional (3D) structures because UV radiation cannot penetrate deeply into the treated coatings due to strong light attenuation as a result of intense UV-light absorption and scattering. The latter is inversely proportional to the fourth power of the wavelength of light, so a short wave UV light is scattered much higher than the visible or near-infrared one. As a result, depth of penetration into polymerizable material is significantly limited for UV light in comparison with near infrared. Therefore, photopolymerization is generally used for thin-film system due to the limited penetration of incident UV light in bulk systems.

The use of ultraviolet (UV) light in combination with photoinitiators to produce polymeric nanocomposite films is one of the most rapid and effective polymerization methods. The main advantage of the use of UV light in combination with photoinitiators is the creation of well-defined patterned structures. However, inorganic nanoparticles are not easily dispersed in organic polymer matrices unless a dispersing agent is used. Furthermore, a refractive index mismatch can considerably increase the scattering of the incident UV light.

UV photolithography is ideal for the direct incorporation of nanocomposites into specific parts of systems and devices for the patterning of nanocomposites using UV polymerization. Photolithographically prepared nanocomposite structures can be used for (1) the selective deposition of molecules, which have specific affinity to the photopolymerized material; (2) the creation of molecular “sandwiches;” (3) the deposition of cells; (4) microfluidic devices; (5) sensors; (6) photoemitting parts within devices; and more.

Reinforcing agents must be used to increase the properties of neat (undoped) polymers. For example, the insufficient hardness of UV-cured products often results in scratch damages on their surfaces. The final properties of UV-cured products can be improved or modified by optimizing the resin formulations or adding reinforcing fillers, past what can be achieved through chemical cross-linking, alone. Fillers, such as alumina and silica, can be mixed with polymers at the micron scale. Nanoparticles are increasingly used as fillers in polymers to improve properties like abrasion resistance, stiffness, barrier properties, thermal and electrical conductivity and refractive index. These nanoparticles are generally inorganic materials, which differ from the organic polymer matrix in terms of their composition, structure, and refractive indices. They occupy a certain volume, and interact with the functional groups of polymers to confine possible mobility of polymer chains. Several groups have investigated how to incorporate nanoparticles in polymer matrixes to obtain transparent polymer composites. In situ polymerization of nanoparticles in polymer matrices to obtain bulk polymer-nanoparticle composites often results in the loss of transparency in the final product. In large bulk polymerization of nanocomposites, phase separation of the nanoparticles during the polymerization process regularly occurs which leads to agglomeration of the nanoparticles and a turbid final product because of light scatter. Several techniques have been developed to incorporate various nanoparticles in transparent polymer composite materials which prevent agglomeration of the nanoparticles during the polymerization process. These techniques are derived from either (1) ligand exchange of the nanoparticles' original stabilizing ligands or (2) the selection of appropriate polymeric hosts that inhibit agglomeration of the nanoparticles during polymerization. Decrease in transparency of the polymeric nanocomposite is especially evident in the UV range, resulting in a limited depth of the UV-induced photopolymerization, patterning, and curing of the polymeric nanocomposite materials.

Ultraviolet (UV) radiation-mediated photochemical reactions are extremely important in materials science, advanced imaging, chemical biology and drug-delivery systems. For biomedical applications, UV photons can manipulate the functions of biomolecules or mediate on-demand drug release in live systems via effective photoactivation. However, commonly used UV lamps or lasers produce an excessively large radiation area and have major drawbacks, such as severe phototoxicity and significantly limited tissue penetrability. Thus, an in situ generation of UV light utilizing nanoparticles with a biocompatible low-energy near-infrared (NIR) excitation is quite desirable since it can spatiotemporally restrict photochemical reactions in the nanometer regime with minimal photo-damage and significantly enhanced light penetration depth.

When excited by high-peak power (˜10⁸ W·cm⁻²) pulsed lasers, organic luminophores and semiconductor nanocrystals can produce two- or three-photon excited luminescence in the visible region. Yet, upconversion from NIR to UV via this direct multi-photon excitation is quite inefficient.

An alternative is the lanthanide (Ln)-doped upconverting nanoparticle (UCNP) containing host NaYF₄ matrix, sensitizer Yb³⁺ and emitter Tm³⁺ ions, which can absorb NIR light from a continuous wave (CW) light source and emit photons at multiplex shorter wavelengths that extend to the UV region (FIG. 1). Because many Ln³⁺ ions have ladder-like hierarchical excited states with long lifetimes, such an upconversion process is significantly more efficient than the conventional, multi-photon-absorption-based processes.

However, the NIR-to-UV efficiency has remained low and the choice of the UV emitting UCNPs has been only limited to β-NaYF₄:(20-30%)Yb, (0.2-0.5%)Tm or β-NaYF₄:(20-30%)Yb, (0.2-0.5%)Tm/β-NaYF₄. The required high laser power density and their concomitant heat side effects have obviously hindered the applications of such NIR-to-UV UCNPs. Thus a more efficient generation of UCNPs needs to be developed. Yet, while strategies to enhance NIR-NIR emissions have been demonstrated, no approach has yet been established to systematically engineer UCNPs in order to enhance NIR to UV efficiency and their resistance to various quenching problems induced by high-frequency hydroxyl (OH) vibration energy containing molecules (e.g., water, proteins) in live systems.

### SUMMARY OF THE DISCLOSURE

In an aspect, provided is a core-shell nanoparticle and core-shell nanoparticles. In an embodiment, a core-shell nanoparticle comprises a core comprising hexagonal phase (β-)NaYbF₄ doped with Tm and shell comprising NaYF₄, NaLuF₄, or NaGdF₄. In an embodiment, the Tm is present at 0.1% by weight to 5% by weight. In an embodiment, the core-shell nanoparticle has a diameter of 15 nm to 100 nm. In an embodiment, the core of the core-shell nanoparticle has a diameter of 8 nm to 90 nm. In an embodiment, the shell of the core-shell nanoparticle has a thickness of 3 nm to 50 nm.

In an aspect, provided is a composition comprising a plurality of the core-shell nanoparticles. In an embodiment, the composition comprises a plurality of the core-shell nanoparticles, a photoinitator, and a polymerizable material (e.g., a polymerizable material comprising at least one monomer or curable (e.g., cross-linkable) prepolymerized polymer). In an embodiment, the composition comprises a polymerizable material comprising at least two types of monomers and each type of monomer has a different structure. In an embodiment, the composition comprises the core-shell nanoparticles at 0.1% by weight to 50% by weight.

In an aspect, provided is a method of polymerizing a polymerizable material using the core-shell nanoparticles. In an embodiment, the method comprises contacting a polymerization mixture comprising the core-shell nanoparticles, a photoinitiator, and a polymerizable material such that visible light, ultraviolet radiation, or a combination thereof is generated and a polymer is formed. In an embodiment, the polymerization mixture is present as a layer and a layer comprising the polymer and the plurality of the core-shell nanoparticles is formed. In an embodiment, the polymerization mixture comprises a plurality of the core-shell nanoparticles having a different blue visible and/or UV wavelength emission. In an embodiment, the polymerization mixture is contacted with near infrared light in a pattern and the polymer is formed in a pattern corresponding to the pattern of near infrared light.

In an aspect, provided is a method of identifying a product as counterfeit. In an embodiment, the method comprises contacting a product with near-infrared light, and observing at least a portion of the visible and/or ultraviolet emission from a product tag comprising a core-shell nanoparticle or core-shell nanoparticles of claim 1, wherein observation of the emission specifically identifies a product having the product tag. The absence of emission from a product tag identifies the product as counterfeit. In an embodiment, the product tag comprises a layer or layers of the nanoparticles on at least a portion of a surface of a tagged product. In an embodiment, the layer or layers of nanoparticles comprises a pattern of the core-shell nanoparticles. In an embodiment, the product tag comprises at least two core-shell nanoparticles having different emission wavelengths.

In an aspect, provided is a nanocomposite. In an embodiment, the nanocomposite comprises a polymer and the core-shell nanoparticles. In an embodiment, the nanocomposite is in the form of a layer or a plurality of layers. Each of the layer(s) may be patterned. In an embodiment, the layer(s) is/are disposed on a substrate. In an embodiment, the nanocomposite is a bulk structure.

In an aspect, provided are products comprising the product tag. In an embodiment, the product is a commercial product.

### BRIEF DESCRIPTION OF THE FIGURES

For a fuller understanding of the nature and objects of the disclosure, reference should be made to the following detailed description taken in conjunction with the accompanying figures, in which:

FIG. 1 describes (a) upconverting nanoparticles suspended under excitation with 980 nm near infrared (NIR) light and (b) their upconversion spectra acquired under 980 nm laser excitation. There is a strong photoluminescence band at roughly 350 nm (UV) (A), which can be used for in situ UV-induced photopolymerization. In addition, strong emission is observed in blue (B) (˜440-480 nm), far-red (C) and near infrared (NIR) (D) ranges;

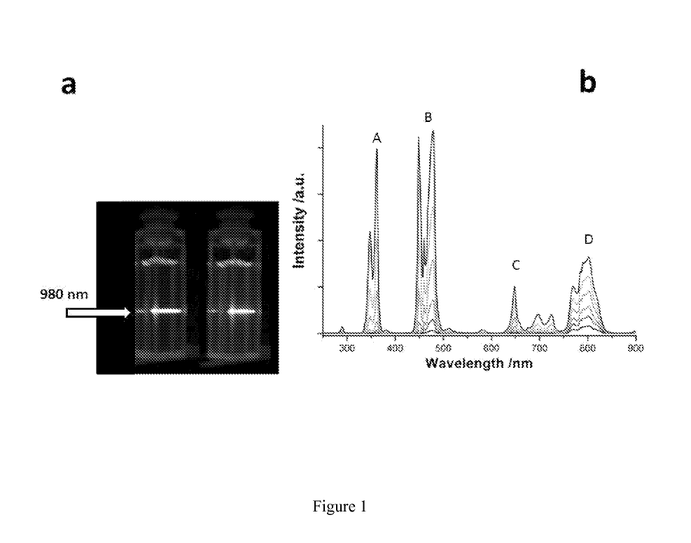

FIG. 2 describes (a) transmission electron microscopy images of hexagonal NaYbF₄:Tm/NaYF₄ nanoparticles, displaying the clear core/shell structure and (b) the upconversion luminescence of colloidal hexagonal NaYbF₄:Tm/NaYF₄ nanoparticles dispersed in hexane, showing enhanced UV and blue emissions under 980 nm excitation;

FIG. 3 describes an SU-8 based nanocomposite polymerized on glass substrate as a result of irradiation with a 980 nm laser (˜1 W/cm²), with blue color emission visible under 980 nm excitation (A); and

FIG. 4 describes photopatterned polymerization of the nanocomposite induced by the NIR (980 nm) irradiation. The top two images describe the geometric pattern of SU-8 based nanocomposite film polymerized with photomask under 980 nm excitation. The visible blue color (A) results from photoluminescence caused by excitation with 980 nm. The bottom two images show confocal microscopy images of the NIR-patterned (980 nm) polymer nanocomposite. The left bottom photograph shows reflection, and the bottom right shows transmission.

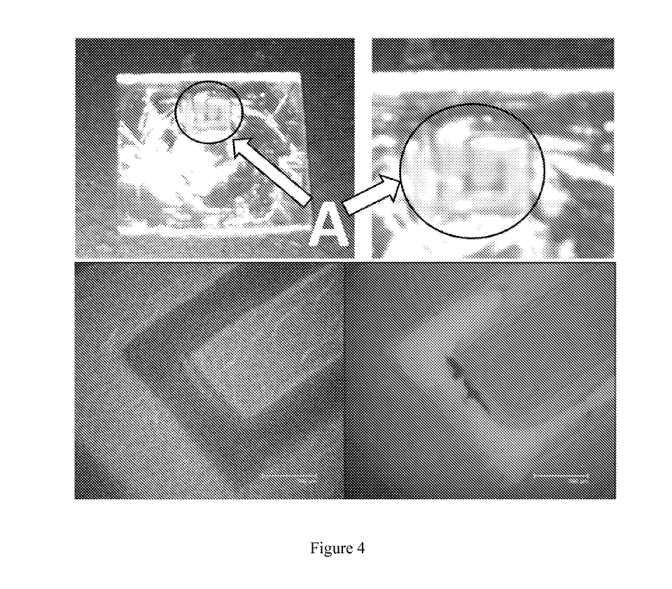

### DETAILED DESCRIPTION OF THE DISCLOSURE

The present disclosure provides core-shell nanoparticles, methods of making the nanoparticles, and methods of using the nanoparticles. The nanoparticles are upconversion luminescence nanoparticles. The nanoparticles can be used, for example, for near-infrared-induced in situ photopolymerization, photocuring, and photoactivation.

The core-shell nanoparticles upconvert near infrared light to UV and/or visible blue light. The UV and/or visible blue light can initiate photochemical reactions in situ. For example, the upconverted UV (e.g., ˜320-380 nm) or visible blue (e.g., 440-480 nm) light can polymerize photopolymerizable materials (e.g., monomers) or cure (cross-link) prepolymerized materials (e.g., resins).

In an aspect, the present disclosure provides core-shell nanoparticles (also referred to herein as nanocrystals). The nanoparticles comprise a core and a shell. For example, the nanoparticles have the general formula X:Y/Z, wherein X is β-NaYbF₄; Y is the dopant of Tm, and Z is a shell selected from the group consisting of NaYF₄, NaLuF₄, and NaGdF₄. In an embodiment, the nanoparticles consists of a core and a shell.

The core-shell nanoparticles can have different sizes and ranges of size. In an embodiment, the longest dimension (e.g., a diameter for spherical or substantially spherical) of the core/shell nanoparticles is between 15 nm and 100 nm, including all integer nm values and ranges therebetween. By substantially spherical it is meant that the shape of the nanoparticles can be circumscribed by a sphere. In an embodiment, average of the longest dimension (e.g., a diameter for spherical or substantially spherical) of a plurality of the core/shell nanoparticles is between 15 nm and 100 nm, including all integer nm values and ranges therebetween. Nanoparticles having a size in this range are desirable for near infrared upconversion. If the core/shell nanoparticles are smaller than 15 nm the upconversion to UV or visible blue light may be inefficient for practical application. Particles smaller than 15 nm have too large of a surface to volume ratio and an increased number of lanthanide ions on the surface are exposed to the surrounding quenching. When an excessive number of lanthanide ions on the surface are exposed to the surrounding quenching centers, this may result in a lower efficiency (relative to larger particles) in upconversion to UV or visible blue light.

The core of the nanoparticles comprises β-NaYbF₄; Y is the dopant (Tm). The core can have a variety of sizes. In an embodiment, the longest dimension (e.g., a diameter for spherical or substantially spherical cores) of core of the nanoparticles is between 8 nm and 90 nm, including all values to the nm and ranges therebetween. In an embodiment, the average of the longest dimension (e.g., a diameter for spherical or substantially spherical) of the core of a plurality of the nanoparticles is between 8 nm and 90 nm, including all values to the nm and ranges therebetween. In an embodiment, the core has a longest dimension of 30 nm to 90 nm. In an embodiment, the average of the longest dimension of the cores of a plurality of nanoparticles is 30 nm to 90 nm. In an embodiment, the core consists of β-NaYbF₄; Y is the dopant (Tm).

The core is doped with Thulium (Tm). Tm is present in the core as Tm⁺³ ions. In an embodiment, the dopant, Tm, is present at a concentration between 0.1% and 5%, including all % values to 0.05 and ranges therebetween. If the dopant concentration becomes too low (e.g., less than 0.1%), there is insufficient emission for photo applications. If the dopant concentration is too high (e.g., greater than 5%), the risk for luminescence quenching due to cross relaxations between Tm³⁺ ions becomes too great.

The shell is disposed on the core of the nanoparticle. The shell comprises NaYF₄, NaLuF₄, NaGdF₄, or a combination thereof. In an embodiment, the shell completely encompasses the core. In an embodiment, the thickness of the shell is between 3 nm and 50 nm, including all nm values and ranges therebetween. In an embodiment, the average thickness of the shells of a plurality of nanoparticles is between 3 nm and 50 nm, including all nm values and ranges therebetween. If the shell is smaller than 3 nm, the shell may be unable to sufficiently suppress the quenching effect from the particle environment because shell portions smaller than 3 nm may not sufficiently isolate the lanthanide ions in the core nanoparticle from the surrounding luminescent quenchers, such as the vibration groups contained in the polymers or photoinitiators. The inadequate isolation of the core nanoparticles from the surrounding quenching centers generally results in inadequate efficiency in upconversion to UV or visible blue light. In an embodiment, the shell consists of NaYF₄, NaLuF₄, NaGdF₄, or a combination thereof.

The core-shell nanoparticles can upconvert NIR light. In an embodiment, the nanoparticles upconvert NIR light having a wavelength of 900 nm to 1080 nm, including all wavelength values to the nm and ranges therebetween, to UV light having a wavelength of 320 nm to 380 nm, including all wavelength values to the nm and ranges therebetween, blue visible light having a wavelength of 430 nm to 500 nm, including all wavelength values to the nm and ranges therebetween, or a combination thereof. In an embodiment, the nanoparticles upconvert NIR light having a wavelength of 910 nm to 990 nm to UV light having a wavelength of 320 nm to 380 nm, blue visible light having a wavelength of 440 nm to 480 nm or a combination thereof. In an embodiment, the nanoparticles upconvert NIR light having a wavelength of 970 nm to 980 nm to UV light having a wavelength of 320 nm to 380 nm, blue visible light having a wavelength of 440 nm to 480 nm or a combination thereof.

In an aspect, the present disclosure provides a method of making the core-shell nanoparticles of the present disclosure. The methods convert cubic phase (α-)NaYbF₄ nanoparticles doped with Tm to hexagonal phase (β-)NaYbF₄ nanoparticles doped with Tm.

In an embodiment, the method of making core-shell nanoparticles, the nanoparticles comprising a core comprising hexagonal phase β-NaYbF₄ doped with Tm and shell comprising NaYF₄, NaLuF₄, or NaGdF₄ comprises: providing cubic phase (α-)NaYbF₄ nanoparticles doped with Tm; converting the cubic phase (α-)NaYbF₄ nanoparticles doped with Tm to hexagonal phase (β-)NaYbF₄ nanoparticles doped with Tm; and coating the hexagonal phase (β-)NaYbF₄ nanoparticles doped with Tm with a shell comprising NaYF₄, NaLuF₄, or NaGdF₄, such that the core-shell nanoparticles are formed.

The cubic phase (α-)NaYbF₄ nanoparticles doped with Tm can be converted to hexagonal phase (β-)NaYbF₄ nanoparticles doped with Tm by heating a solution comprising the cubic phase (α-)NaYbF₄ nanoparticles, a solvent (e.g., hexane), sodium trifluoracetate, a fatty acid (e.g., oleic acid and linoleic acid), and an alkene such as octadecene. The solution is degassed and dried (e.g., by purging the solution with an inert gas such as, for example, argon) prior to heating. The degassed and dried solution is heated such that the cubic phase (α-)NaYbF₄ nanoparticles doped with Tm are converted to hexagonal phase (β-)NaYbF₄ nanoparticles doped with Tm. The solution is heated at 300° C. or greater. For example, the solution is heated to 320° C. and the temperature maintained at 320° C. for 30 minutes. Based on the solution components and conditions (e.g., heating temperature and time) varying nanocrystal sizes and morphologies may be obtained.

In an aspect, the present disclosure provides nanocomposite precursor compositions. For example, the precursor compositions can be used to form nanocomposite layers (e.g., patterned layers). The nanocomposite comprises a plurality of the core-shell nanoparticles and a polymer or copolymer.

In an embodiment, the nanocomposite precursor composition comprises a plurality of the core-shell nanoparticles of the present disclosure; at least one photoinitiator; and a polymerizable material.

In an embodiment, the nanocomposite precursor composition comprises a plurality of the core-shell nanoparticles of the present disclosure; at least one photoinitiator; and at least two photopolymerizable monomers of the same or different compositions.

The core-shell nanoparticles can be present in the composition at a variety of loadings. In an embodiment, the nanoparticles are present at 0.1% by weight to 90% by weight, including all % by weight values to 0.1 and ranges therebetween. In an embodiment, the nanoparticles are present at 0.1% by weight to 50% by weight. In an embodiment, the nanoparticles are present at 1% by weight to 10% by weight.

The photoinitiator may be any known or developed photoinitiators capable of polymerizing, curing, or initiating a chemical reaction when exposed to UV and/or visible blue light (e.g., ˜320-380 nm or ˜440-480 nm). Suitable photoinitiators are known in the art. Suitable photoinitiators are commercially available. Examples of suitable photoinitiators include radical initiators (e.g., Darocur® and Irgacure® from BASF), cationic and anionic photoinitiators (e.g., cationic and anionic photoinitiators from Sigma-Aldrich, cationic catalysts available from Polyset Co., Inc).

Polymerizable materials includes, for example, monomers and/or prepolymerized materials that can be cross-linked. Any known or developed polymerizable material that can be polymerized by UV and/or visible light (e.g., visible blue light) or by an initiator that is initiated by UV and/or visible light (e.g., visible blue light) (i.e., photopolymerizable monomers or photopolymerizable prepolymerized materials) can be used. In an embodiment, the polymerizable material (e.g., monomer or prepolymerized materials) have a carbon-carbon double bond that can be reacted to form a polymer. Examples of suitable monomers include epoxides, acrylates (e.g., methacrylates), vinyl monomers, and their combinations with maleimides. Prepolymerized materials (e.g., resins such as epoxy resins) can be used. Prepolymerized materials can be cured. Photoresists comprising monomers and/or prepolymerized materials can be used (e.g., Riston series from Dupont, RD series from Hitachi, DiaEtch series from HiTech, SU-8 available from Miller Stephenson Chemical Co., etc.). Mixtures of monomers (resulting in formation of a copolymer) and prepolymerized materials may be used. Suitable monomers, resins, photoresists, etc. are commercially available.

A variety of solvents can be used. The polymerizable materials (e.g., monomer(s) and prepolymerized materials) have at least a measurable solubility in the solvent which is employed. Examples of suitable solvents include aromatic solvents (e.g., benzene, and toluene), dioxane, alkanes (e.g., hexane), chlorinated solvents (e.g., chloroform), alcohols, water, etc.

The precursor composition may comprise two or more different core-shell nanoparticles. In this case, each of the two or more nanoparticles may have emission profiles that can be independently identified.

The nanocomposite precursor composition can be formed by mixing the core-shell nanoparticles, the photoinitiator(s); and the monomer(s). In an embodiment, the mixing of nanoparticles and monomers is carried out at room temperature and at a pressure of 1 atmosphere.

In an aspect, the present disclosure provides uses of the core-shell nanoparticles. The core-shell nanoparticles can be used in applications such as, for example, photolithography applications, photopatterning applications, fabrication of polymer coatings, medical applications, dental applications, and anticounterfitting applications.

The core-shell nanoparticles can be used to upconvert near infrared light to UV or visible blue light. The upconverted UV or visible blue light can polymerize photopolymerizable materials.

In an embodiment, a method for upconverting near infrared light to UV or visible blue light comprises contacting a core-shell nanoparticle or a plurality of core-shell nanoparticles with near-infrared light, wherein ultraviolet or visible light (e.g., visible blue light) is produced.

The core-shell nanoparticles can be used to polymerize polymerizable materials (e.g., monomer(s) or prepolymerized material(s)). For example, the nanoparticles can be used to polymerize a monomer or monomers using near infrared light.

In an embodiment, a method of polymerizing polymerizable materials using the core-shell nanoparticles comprises: contacting a polymerization mixture comprising a plurality of the core-shell nanoparticles, a photoinitiator, and at least two monomers having the same or different structure with near infrared light such that visible light, ultraviolet light, or a combination thereof is generated and a plurality of monomers react to form a polymer.

In an embodiment, the near infrared wavelength used is between 900 nm and 1080 nm. In embodiment, the generated (i.e., upconverted) visible blue wavelength used is between 430 nm and 500 nm. In an embodiment, the generated (i.e., upconverted) ultraviolet wavelength used is between 320 nm and 380 nm.

Patterned polymer structures may be formed. By contacting selected portions of the polymerization mixture with NIR light, which results in polymer formation corresponding to the selected portions exposed to the NIR light, patterned polymer structures may be formed. The NIR light may be passed through a mask (which permits only NIR light to pass through selected portions of the mask) or provided by direct-write methods (e.g., laser scanning photolithography). For example, patterned polymer structures having a feature size of 500 nm or greater can be formed.

Polymerization of a monomer or monomers (e.g., a layer of monomer or monomers) or curing (cross-linking) of the prepolymerized material may be carried out behind a material (e.g., a layer of material) that absorbs or scatters ultraviolet or visible light, which prevents a polymerizable material (e.g., a layer of polymerizable material) from polymerizing. The NIR light passes through the material prior to contacting the polymerization mixture. In an embodiment, the polymerization layer is present behind a material that absorbs or scatters ultraviolet or visible light (e.g., a layer of such material).

It may be desirable to form a nanocomposite film that is optically transparent and non-opaque. Accordingly, in an embodiment, core-shell nanoparticles having a size of less than 100 nm are used to produce optically transparent, non-opaque nanocomposite.

The nanoparticles can be used in dental applications. Core-shell nanoparticles exhibiting a photoluminescence at ˜440-480 nm having a desirable intensity can be used in a dental application, where ˜450 nm light sources are routinely used for photopolymerization. Mixing the nanoparticles with commercially available dental resin polymerizable with 450 nm light, the NIR curable nanocomposite can be obtained, which will allow for the depth of polymerization to be increased and its uniformity to be increased, relative to conventional, blue-light curable resin. At the same time, the inorganic NaYbF₄:Tm core-based nanoparticle formulations can serve as nanofillers in the dental resins, improving their physical properties. Moreover, nanoparticle shells can be engineered to provide better compatibility/binding strength with the organic constituents of the nanocomposite, yet maintaining a high NIR-to UV/blue conversion efficiency.

The nanoparticles can be used in anti-counterfeiting applications. The core-shell nanoparticles can be used in methods of identifying a product (e.g., commercial products). For example, products can be tagged with the nanoparticles such that they can be selectively identified. In an embodiment, the product is tagged with a color-coded multilayer pattern.

In an embodiment, a method of identifying a product comprises contacting a product with near-infrared light (e.g., using a laser diode), and observing, if present, visible and/or ultraviolet emission from a product tag comprising the core-shell nanoparticle or core-shell nanoparticles, where the emission specifically identifies a product having the product tag. The absence of emission from a product tag identifies the product as counterfeit.

The product tag comprises the core-shell nanoparticles. The core-shell nanoparticles can be integrated in the product (e.g., the nanoparticles are embedded in product, such as embedded in the plastic (e.g., thermoplastic) of the product) or in a coating on the product (e.g., the nanoparticles are disposed in paint or lacquer), a label on the product (e.g., a label comprising the nanoparticles on the surface of the product), or integrated or disposed on the packaging of the product).

For example, the core-shell nanoparticles are present as a nanocomposite. The nanocomposite comprises at least one core-shell nanoparticle disposed in a polymer. The product tag can be a continuous layer or layers disposed on a least a portion of a surface of the product or a patterned layer or layers disposed on at least a portion of the surface. In an embodiment, the product tag comprises a layer or layers comprising the nanoparticles (e.g., a nanocomposite) on at least a portion of a surface of a tagged product. In an embodiment, the layer or layers comprising the nanoparticles is a patterned layer having a predetermined pattern. In an embodiment, the product tag comprises at least two types of core-shell nanoparticles having different emission wavelengths. In an embodiment, the product tag comprises at least two layers containing nanoparticles that can produce different patterns depending on excitation power density.

In an aspect, the present disclosure provides a nanocomposite. The nanocomposite comprises a polymer and the core-shell nanoparticles. The nanocomposite can be formed by the methods disclosed herein. Accordingly, in an embodiment, the nanocomposite is formed by a method of polymerization disclosed herein.

In an embodiment, the nanocomposite is in the form of a layer. The nanocomposite layer can be formed on a substrate (e.g., a product). In an embodiment, the layer is disposed on a substrate. The layer can be continuous. The layer can be patterned domains (i.e., discrete nanocomposite structures) in a desired, predetermined pattern. For example, depending of the size of nanoparticles used, the layer can have a thickness of 100 nm to 5 millimeters.

In an embodiment, the nanocomposite is a bulk structure. The structure be three-dimensional structure. For example, the bulk structure can have a volume of up to 200 cm³.

In an aspect, the present disclosure provides products comprising the product tag. The product tag can be the nanocomposite in any form described herein.

The steps of the methods described in the various embodiments and examples disclosed herein are sufficient to carry out the methods of the present disclosure. Thus, in an embodiment, the method consists essentially of a combination of the steps of the methods disclosed herein. In another embodiment, the method consists of such steps.

The following descriptions provide specific examples of the present disclosure. Those skilled in the art will recognize that routine modifications to these embodiments can be made which are intended to be within the scope of the disclosure.

### Example 1

### Manufacture of Nanoparticles

This example describes making of the core-shell nanoparticles.

Materials: Y₂O₃ (99.99%), Gd₂O₃ (99.99%), Lu₂O₃ (99.99%)Yb₂O₃ (99.9%), Tm₂O₃ (99.99%), CF₃COONa (99.9%), CF₃COOH, 1-octadecene (90%), oleic acid (90%) were all purchased from Sigma-Aldrich and used without further purification. The trifluoroacetates of Y, Yb, Gd, Lu, and Tm were prepared by dissolving corresponding lanthanide oxides into 50% CF₃COOH water solutions at an elevated temperature at 90° C. and then dried in vacuum.

Synthesis of Lanthanide-Doped Upconverting β-NaYbF4:Tm³⁺ (0.5%)/NaREF4 Core-Shell nanocrystal (RE=Y, Gd or Lu) The upconverting core-shell nanocrystals were prepared using a three-step procedure. The first two steps in the procedure encompass the synthesis of the cubic phase core (α-NaYbF4:Tm³⁺) and its subsequent conversion to the hexagonal phase (β-NaYbF4:Tm³⁺). The last step in the procedure encompasses the coating of the NaREF4 shell to the hexagonal core. All chemical used in the synthesis were purchased from Sigma-Aldrich and used as received.

The first step of the procedure was to synthesize the α-NaYbF4:Tm³⁺ (0.5%) core. In a typical synthesis of the cubic core, 0.4975 mmol Yb₂O₃ and 0.0025 mmol Tm₂O₃ were mixed with 10 mL of 50% trifluoroacetic acid in a 100-mL three-necked flask and then refluxed at 95° C. until completely dissolved. The RE(CF₃COO)₃ (RE=Yb+Tm) precursor was obtained by evaporating the clear solution to dryness under an Ar purge. Sodium trifluoroacetate was then added together with oleic acid (90% tech grade), oleylamine (70% tech grade) and octadecene (90% tech grade). The solution was then degassed at 120° C. for 30 minutes under Ar to remove the remaining water and oxygen. The resulting solution was then heated to 300° C. and kept at this temperature for 30 minutes before naturally cooling down to room temperature. Addition of 10 mL ethanol to precipitate the nanocrystals was performed and then followed by centrifugation at 9,000 rpm for 7 minutes. The precipitate was collected and then dispersed in 10 mL hexane without further washing to avoid loss of the cubic core product. Variation of temperature, precursor concentration, and reaction time varied the size of the resulting core nanoparticles from 4 to 10 nm.

The second step of the procedure was to convert the α-NaYbF4:Tm³⁺ (0.5%) core to a hexagonal β-NaYbF4:Tm³⁺ (0.5%) core. To convert the α-NaYbF4:Tm³⁺ to the hexagonal phase, 5 mL of the hexane solution containing the cubic core was added to the mixture of sodium trifluoroacetate, oleic acid and octadecene. Residual water and oxygen were again removed by degassing at 120° C. for 30 minutes under Ar. The resulting solution was then heated to 320° C. and kept at this temperature for 30 minutes before naturally cooling down to room temperature. An excess amount of ethanol was then added to precipitate the nanocrystals and then centrifuged at 9,000 rpm for 7 minutes. Variation of the molar ratio between the cubic core and the sodium trifluoroacetate can tune the resulting size from 10-70 nm.

The third step of the procedure was to coat the NaREF4 shell on the hexagonal core. Coating of the NaREF4 shell on the hexagonal core utilized the exact same steps of degassing and heating described in the synthesis of the sized β-NaYbF4:Tm³⁺ (0.5%) core above except that the starting solution mixture consisted of an RE(CF₃COO)₃ shell precursor, β-NaYbF4:Tm³⁺ (0.5%) core, Na(CF₃COO) in oleic acid and octadecene. The RE(CF₃COO)₃ shell precursor was prepared by mixing RE₂O₃ in 50% concentrated trifluoroacetic acid then refluxing at 95° C. to get a clear solution. The shell precursor was obtained by evaporating the solution to dryness under Ar. By selecting the size of core nanoparticles as well as the molar ratio between the core and the shell precursor, the size is able to be tuned from 20-100 nm.

### Example 2

### In Situ Photopolymerization and UV Curing

This example describes use of the core-shell nanoparticles in in situ polymerization methods.

To demonstrate proof of principle for the near-infrared light induced photopolymerization in situ, which occurs as a result of NIR-to-UV upconversion in the nanofillers, NaYbF₄:Tm/NaYF₄ nanoparticles were introduced into a standard, UV-polymerizable formulation. The photoresist SU-8 (purchased from Miller Stephenson Chemical Co.) was used. SU-8 is a multifunctional, highly branched polymeric epoxy resin, which contains bisphenol, a novolac glycidyl ether. A photoinitiator PC-2506 (Polyset Co, Inc.), which undergoes a photochemical transformation upon absorption of a UV photon and generates a photoacid, was added to induce cross-linking of the SU-8.

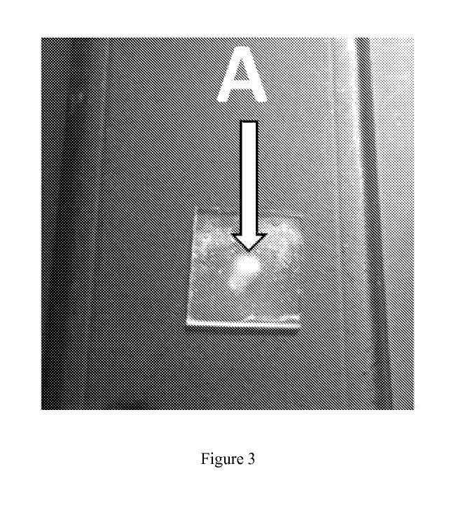

The photoresist epoxy resin and photoinitiator were added to nanoparticles suspension in cyclopentanon. The overall mixture was stirred and solution spin coated on the glass substrate. After spin coating, the sample was soft baked at 95° C. for 60 minutes to evaporate the solvent before laser exposure. The sample, naturally cooled to room temperature, was irradiated with 980 nm wavelength laser diode (power density of ˜1 W/cm²) for 60 minutes and the exposed sample was post baked for 30 minutes at 95° C. to accelerate cross-linking. A propylene glycol methyl ether acetate (PGMEA) was used for development, over 9 hours. FIG. 3 shows the polymer nanocomposite film that remained after development, when all non-cross-linked SU-8 was removed by washing with solvent. As one can see, transparent film of the polymer nanocomposite was formed on the glass substrate, displaying visible to eye photoluminescence under excitation of 980 nm. It is important to note that the lens-like bulge in the center of film is associated with higher power density of in the center of irradiating laser beam (Gaussian profile of the beam intensity). A higher power density in laser irradiation spot resulted in brighter UV emission from the nanofillers and, as a result, in a thicker layer of the polymerized nanocomposite material.

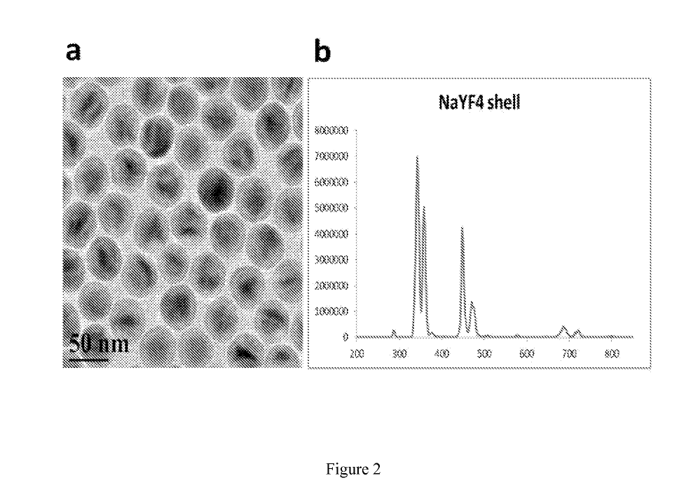

The core/shell UCNPs were further characterized by the use of transmission electron microscopy (TEM), where the heavy atom (i.e. Yb³⁺) enriched core region showed stronger electron scattering than outer shell. A clear core/shell structure can be shown in the TEM images (See FIG. 2 a).

While the disclosure has been particularly shown and described with reference to specific embodiments (some of which are preferred embodiments), it should be understood by those having skill in the art that various changes in form and detail may be made therein without departing from the spirit and scope of the present disclosure as disclosed herein.

What is claimed is:

1. A core-shell nanoparticle comprising a core comprising hexagonal phase (β-)NaYbF₄ doped with Tm and shell comprising NaYF₄, NaLuF₄, or NaGdF₄.

2. The core-shell nanoparticle of claim 1, wherein the Tm is present at 0.1% by weight to 5% by weight.

3. The core-shell nanoparticle of claim 1, wherein the core-shell nanoparticle has a diameter of 15 nm to 100 nm.

4. The core-shell nanoparticle of claim 1, wherein the core of the core-shell nanoparticle has a diameter of 8 nm to 90 nm.

5. The core-shell nanoparticle of claim 1, wherein the shell of the core-shell nanoparticle has a thickness of 3 nm to 50 nm.

6. A composition comprising a plurality of the core-shell nanoparticles of claim 1, a photoinitator, and a polymerizable material.

7. The composition of claim 6, wherein the composition comprises at least two types of monomers and each type of monomer has a different structure.

8. The composition of claim 6, wherein the composition comprises the core-shell nanoparticles at 0.1% by weight to 50% by weight.

9. A method of polymerizing a polymerizable material using the core-shell nanoparticles of claim 1 comprising: contacting a polymerization mixture comprising the core-shell nanoparticles, a photoinitiator, and a polymerizable material such that visible light, ultraviolet radiation, or a combination thereof is generated and a polymer is formed.

10. The method of claim 9, wherein the polymerization mixture is present as a layer and a layer comprising the polymer and the plurality of core-shell nanoparticles is formed.

11. The method of claim 9, wherein the polymerization mixture comprises a plurality of the core-shell nanoparticles having a different blue visible and/or UV wavelength emission.

12. The method of claim 9, wherein the polymerization mixture is contacted with near infrared light in a pattern and the polymer is formed in a pattern corresponding to the pattern of near infrared light.

13. A method of identifying a product comprising the product tag contacting a product with near-infrared light, and observing at least a portion of the visible and/or ultraviolet emission from the product tag comprising a core-shell nanoparticle or core-shell nanoparticles of claim 1, wherein observation of the emission specifically identifies the product having the product tag.

14. The method of claim 13, wherein the product tag comprises at least one layer comprising the core-shell nanoparticles on at least a portion of a surface of the product.

15. The method of claim 14, wherein the at least one layer comprising the core-shell nanoparticles comprises a pattern of the core-shell nanoparticles.

16. The method of claim 13, wherein the product tag comprises at least two core-shell nanoparticles having different emission wavelengths.
